(19) United States
(12) Patent Application Publication
(10) Pub. No.: US 2009/0057787 A1
(43) Pub. Date: Mar. 5, 2009

(54) SEMICONDUCTOR DEVICE

(75) Inventors: Takeo MATSUKI, IBARAKI (JP); Kazuyoshi TORII, IBARAKI (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/202,467

(22) Filed: Sep. 2, 2008

(30) Foreign Application Priority Data
Aug. 31, 2007 (JP) 2007-225689

(51) Int. Cl. H01L 29/78

(52) U.S. Cl. 257/411; 257/E29.255

(57) ABSTRACT

There is provided a semiconductor device which can control a reaction caused between a gate electrode and a high-k gate dielectric film, and which has an element structure suitable for higher integration and speed-up. The semiconductor device has an insulated-gate field-effect transistor, wherein the insulated-gate field-effect transistor has: a gate insulating film including a high-k dielectric film; and a gate electrode with a laminated structure including a first conductive layer, and a second conductive layer which has a resistivity lower than that of the first conductive layer, and the first conductive layer is provided on and in contact with the high-k dielectric film, and includes titanium nitride with a density of 5 g/cm³ or more.

This application is based on Japanese patent application NO. 2007-225689, the content of which is incorporated hereinto by reference.

### BACKGROUND

1. Technical Field

The present invention relates to a semiconductor device, especially, to a semiconductor device provided with a metal insulator semiconductor field-effect transistor (MISFET).

2. Related Art

Highly integrated semiconductor circuit is required, and a space of elements and a space between them have been reduced.

The thinnest film thickness of a gate insulating film composed of silicon dioxide or silicon oxy-nitride for advanced CMOS transistors is currently about 2 nm. When the film thickness is further reduced, the gate leak current is increased by the direct tunneling mechanism and the electric power consumption is increased. Furthermore, such a thin silicon dioxide or silicon oxynitride film is composed of several atomic layers, so strict manufacturing control has been required for mass-production of such a thin film with high uniformity.

In order to realize both further downscaling and lower power consumption, a “high dielectric (high-k) material” has been energetically developed to obtain a transistor whose electrical performance is equal to or superior to that of a transistor even when the physical film thickness of high-k dielectric is thicker than that of a silicon dioxide film. The above-described material includes metal silicate which is solid solution of silicon dioxide and group IV oxide such as zirconia and hafnia, metal aluminate which is solid solution of group IV oxide and alumina and the like. A field-effect transistor using metal silicate as a gate dielectric has been disclosed, for example, in Japanese Laid-Open patent publication No. 11-135774.

When polysilicon is used as the gate electrode, the gate capacitance is decreased because the presence of depletion layer of the gate electrode at the gate dielectric interface. When the EOT (equivalent oxide thickness) of the gate insulating film becomes 2 nm or less, the effect of the capacitance reduction caused by the above-mentioned gate depletion cannot be neglected. The capacitance reduction caused by the gate depletion is controlled by substituting metal for polysilicon as the gate electrode material.

On the other hand, there has been considered the reduction in the internal interconnect resistance for high frequency operation of semiconductor devices. Especially, resistance reduction of a gate electrode has been an critical issue because of the influence on RC delay. There has been conventionally adopted a polycide gate (electrode) in order to realize reduction in the resistance of the gate electrode. The polycide gate has a two-layered structure of a polysilicon film and a metallic silicide layer. However, in order to deal with fine interconnect pattern of the future generation, delay time must be decreased by further reduction in the interconnect resistance. For the above-described object, it is effective to use metal for the gate electrode material, that is, a structure in which metallic films are laminated directly on a gate insulating film without inserting a polysilicon film, i.e. a so-called metal gate electrode structure is effective

In the case of a gate electrode structure in which a conventional polysilicon film is provided on the gate insulating film, the threshold voltage of a transistor is decided by the dopant concentrations in the channel region and the dopant concentrations in the polysilicon film. In the case of the metal gate electrode structure, however, the threshold voltage of the transistor is decided by the dopant concentrations in the channel region and the work function of the gate electrode. Accordingly, in the metal gate electrode structure, it is required to use two kinds of materials for the gate electrode, wherein the two materials have a work function suitable, respectively, for an n-type transistor and a p-type transistor. For example, in Japanese Laid-Open patent publication No. 2003-273350, there has been disclosed a structure in which TiCoN is used for the gate electrode of an n-type transistor, and TiCoN with injected oxygen ion is used for the electrode of a p-type transistor.

However, a material having a suitable work function does not necessarily have a fully low resistance. Accordingly, there has been proposed a gate electrode structure in which there are laminated metallic layers for control of the threshold voltage and metallic layers for reduction in the gate resistance. For example, in Japanese Laid-Open patent publication No. 2001-15756, there has been disclosed a structure in which an titanium nitride (TiN) layer as a work function control layer and a refractory metal (Ta, Me, Zr, and the like) as low resistance interconnect are laminated. In Japanese Laid-Open patent publication No. 2001-203276, there has been disclosed a structure in which the gate electrode of a p-type transistor and that of an n-type transistor have a laminated structure of titanium nitride/tungsten, and nitrogen is injected into a titanium nitride layer of the n-type transistor by ion injection to reduce the work function.

Considering the above described background, there has been promoted development of the MISFET (metal insulator semiconductor field effect transistor) which has a structure combining a high-k gate dielectric and a metal gate electrode. In a structure in which a silicon dioxide film or a silicon oxy-nitride film is used as the gate dielectric material, a reaction between a gate electrode material and a gate dielectric during successive heat treatment could be controlled by using refractory metal nitride such as titanium nitride, tungsten nitride, or tantalum nitride for the gate material. However, in a structure in which a refractory metal nitride is deposited on the high-k gate dielectric, there has been caused a problem of, for example, a reaction between the refractory metal nitride and the high-k gate dielectric film, resulting in the work function change or the EOT increase.

### SUMMARY

An object of the present invention is to provide a semiconductor device by which a reaction between a gate electrode and a high-k gate dielectric film is controlled, and which has an element structure suitable both for larger scale integration and higher frequency operation.

In one embodiment, there is provided a semiconductor device having an insulated-gate field-effect transistor, wherein the insulated-gate field-effect transistor has: a gate insulating film including a high-k dielectric film; and a gate electrode which has a laminated structure including a first conductive layer, and a second conductive layer whose resistance is lower than that of the first conductive layer, and the first conductive layer is provided on and in contact with the high-k dielectric film, and includes titanium nitride with a density of 5 g/cm³ or more.

A conductive layer including titanium nitride in {100} orientation can be used as the first conductive layer.

According to the present invention, there can be provided a semiconductor device by which a reaction between the gate electrode and the high-k gate dielectric film is controlled, and which has an element structure suitable for larger scale integration and higher frequency operation.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 shows a cross-sectional view of an MIS field effect transistor which is one example according to an embodiment of the present invention;

FIG. 2 is a view showing heat-treating temperature dependency of a change rate of gate capacitance for explaining an effect of the embodiment;

FIG. 3 is a view showing heat-treating temperature dependency of a change rate of gate leak current for explaining an effect of the embodiment; and

FIG. 4 is a view showing density dependency of a change rate of gate capacitance for explaining an effect of the embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

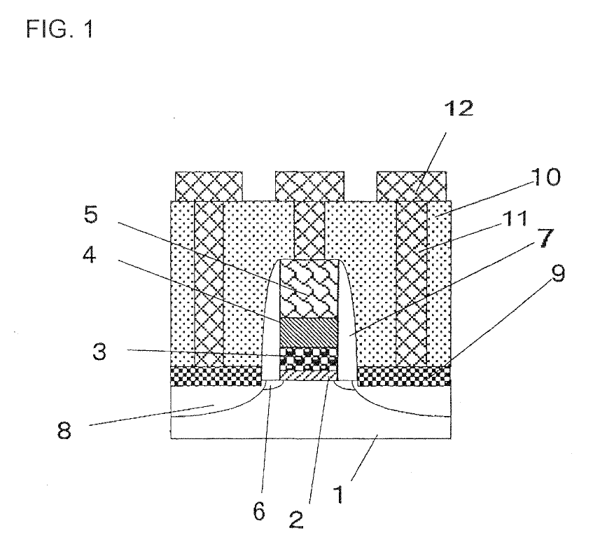

FIG. 1 shows a sectional structure of an insulation gate field-effect transistor (MISFET) which is one example of embodiments according to the present invention. In the drawing, reference numeral 1 denotes a silicon substrate, 2 denotes a silicon oxide film, 3 denotes a hafnium silicon oxy-nitride, 4 denotes a titanium nitride layer, 5 denotes a tungsten layer, 6 denotes an extension region, 7 denotes a gate side wall, 8 denotes a source-drain region, 9 denotes a Ni silicide layer, 10 denotes an insulating interlayer, 11 denotes a contact plug, and 12 denotes interconnect.

The titanium nitride layer 4 is provided on the hafnium silicon oxy-nitride 3 of a high-k dielectric film as a first conductive layer, and, the tungsten layer 5 is provided on the titanium nitride layer 4 as a second conductive layer. The titanium nitride layer 4 is provided on and in contact with the hafnium silicon oxy-nitride 3. A gate electrode is composed by the layers 4 and 5. The titanium nitride layer 4 near the bottom interface (interface between high-k dielectric film) influences control of the threshold voltage. The tungsten layer 5 on the upper layer side has a resistivity lower than that of the titanium nitride layer 4, and has a function reducing the gate resistance. Moreover, the titanium nitride layer 4 in contact with the high-k dielectric film includes titanium nitride with a density of 5 g/cm³ or more. Thereby, the reaction caused between the titanium nitride layer 4 and the high-k dielectric film is controlled. The density of the titanium nitride forming the titanium nitride layer 4 is, preferably, 5.3 g/cm³ or more, and, more preferably, 5.5 g/cm³ or more. Moreover, the titanium nitride layer 4 preferably includes titanium nitride in {100} orientation.

The composition of the titanium nitride layer 4 is preferable, from a view point to obtain more sufficient effects on formation, that the atomic ratio of titanium to nitrogen (Ti/N) is one or more. Furthermore, from a view point to obtain highly reliable gate dielectric, it is more preferable that the ratio is 1 or more and 1.2 or less. When Ti is excessive, there is a possibility that the reliability of the gate dielectric film is reduced, especially for the high temperature heat-treating process.

From a view point to achieve more sufficient effects on the formation, the thickness of the titanium nitride layer 4 is preferably 1 nm or more, and, from a view point of reduction in the resistance, the thickness is desirably 20 nm or less. Moreover, it is preferable, from the view point of the necessity to reduce the gate aspect ratio for finer processing, that the titanium nitride layer 4 is thinner, and that the thickness of the layer 4 is formed thinner than that of the second conductive layer (the tungsten layer and the like) on the upper layer side.

The second conductive layer (the tungsten layer 5 in FIG. 1) is provided on the first conductive layer (the titanium nitride layer 4), and is formed with a material having a resistivity which is lower than that of the titanium nitride forming the first conductive layer. Such the second conductive layer can be formed by a conductive layer with a laminated structure including a metallic layer, a silicide layer, and an n-type or p-type polysilicon layer. As the metallic layer, a tungsten layer, or a molybdenum layer can be formed. As the conductive layer with the laminated structure, a conductive layer with a two layer structure which includes the n-type or p-type polysilicon layer, and the silicide layer which includes at least Ni and Si and is laminated on the polysilicon layer, can be formed. Ni can easily form a silicide by diffusion into polysilicon, Ni is preferable to reduce the resistance of the fine polysilicon gate pattern.

The thickness of the second conductive layer is preferably 30 nm or more and 100 nm or less, and, more preferably, 30 nm or more and 50 nm or less. When it is too thin, the surface roughness causes scattering of electrons, and there is a possibility to increase the resistance. When it is too thick, the gate aspect ratio is increased, and the fine pattern formation becomes difficult.

The gate insulating film in the present embodiment can have a laminated structure which has an other insulation film (the silicon oxide film 2 in the present embodiment) such as a silicon oxide film and a silicon acid nitride film between the high-k dielectric film (the hafnium silicon oxy-nitride 3 in the example shown in FIG. 1) and the silicon substrate. The thickness of the gate insulating film can be properly set according to a general technology.

The above-described field-effect transistor can be formed, for example, as follows.

In the first place, an element-isolating region is formed on a silicon substrate, using a usual shallow trench isolation (STI) formation technology, and, then, a silicon oxide film is formed on an active region enclosed by the above element-isolating region. Here, the silicon oxide film with a physical film thickness of about 0.7 nm was formed by exposing the surface of the silicon substrate to gas containing ozone (03) at 250° C. and at 3 Torr (4.0×10² Pa) for three minutes.

Subsequently, the high-k dielectric film is formed. In the present embodiment, the hafnium silicate film with a physical film thickness of about 2.0 nm was deposited, using a metal organic chemical vapor deposition (MOCVD) method in which hafnium tetra tertiary butoxide (HTB) and a disilane (Si2H6) were used as raw material gas. Subsequently, nitrogen atoms are introduced into the hafnium silicate film to form the hafnium silicon oxy-nitride. Here, nitrogen atoms of about 20% were introduced by exposing the surface of the hafnium silicate film to plasma which mixture gas of argon (Ar) and nitrogen (N2) was generated by micro waves. A method such as a heat treatment in an ammonia atmosphere may be used for introduction of the nitrogen atoms. Thus, the hafnium silicon oxy-nitride is formed. Subsequently, annealing was performed for five seconds in an N2 atmosphere of 5 Torr (6.7e2 Pa) at 1050° C. to consolidate the above-described hafnium silicon oxy-nitride.

Subsequently, a titanium nitride film with a film thickness of 10 nm was formed on the surface of the hafnium nitride silicate film. Then, a tungsten film with a film thickness of 50 nm was formed. A metallic film such as a molybdenum film, instead of the tungsten film, may be formed.

Here, the reactive sputtering method using titanium target was used for deposition of the titanium nitride film. A high-density titanium nitride film with an orientation {100} can be obtained by setting in which the deposition temperature is lowered during sputtering and the direct-current electric power is controlled to make the deposition late low. In the present embodiment, the substrate temperature was a room temperature, the pressure was 0.2 Pa, the direct-current electric power was 1 kW, and nitrogen and Ar were used as sputtering gas.

It is preferable in formation of the titanium nitride film that the substrate temperature is set within a range between the room temperature and 100° C. When the substrate temperature is increased, the density can be raised, but, when it is too high, there is a possibility that the interface state is increased by diffusion of nitrogen into the gate insulating film and changes in the threshold voltage are caused.

The direct current electric power is preferably set within a range of 0.1 kW or more and 5 kW or less. When the direct current electric power is increased, the deposition late can be increased, but, when it is too high, there is a possibility that the damage of the substrate surface is increased by increase of the kinetic energy of particles contributing to the deposition, and the gete leak current is increased because the damage is remained.

The pressure is preferably 0.1 Pa or more and 1 Pa or less, and more preferably 0.1 Pa or more and 0.5 Pa or less. When the pressure is too high, there is a possibility that the film density is reduced because unnecessary gas is taken into the film, and a gap is formed in the film.

Hereinafter, a MIS-type transistor shown in FIG. 1 was formed, according to a general method, by patterning of a gate electrode, forming an extension region 6, forming a gate side wall 7, forming a source/drain region 8, activating impurities, forming a Ni silicide layer 9, forming an insulating interlayer 10, forming a contact plug 11, and forming a metal interconnect 12.

In the above-described embodiment, the hafnium silicon oxy-nitride has been used as a high-k dielectric film for the gate insulating film as one example. But the invention is not limited to this example. A film including an oxide containing hafnium, for example, a film including at least one material selected from hafnium nitride silicate, hafnium silicate, hafnia, and hafnium aluminate can be preferably used as a high-k dielectric film in the present embodiment. Moreover, a film including a high dielectric material such as silicon oxy-nitride (SiON), hafnium silicon oxy-nitoride, hafnium silicate, hafnia, zirconium silicon oxy-nitoride, zirconium silicate, zirconia, hafnium aluminate, lanthanum oxide, alumina, ceria, yttria, and gadolinium oxide, or mixtures of the above materials may be used as a high-k dielectric film in the present embodiment.

Here, in the present embodiment, “high dielectric (high-k) film” generally means an insulation film having a dielectric constant higher than 3.9, which is that of the silicon dioxide (Sio2) used for general gate insulating film, and a film including the above-described high dielectric material is listed as the high dielectric (high-k) film.

In the above-described method for forming a transistor, methods for forming a silicon oxide film 2, and methods for deposition, nitriding, and annealing of hafnium silicate are not limited to the above-described ones.

Hereinafter, the effects of the present embodiment will be explained, based on the experiment results.

The measurement of the orientation of the titanium nitride film was performed by measurement of X-ray diffraction (XRD), and the measurement of the density was done by measurement of X-ray reflectivity (XRR).

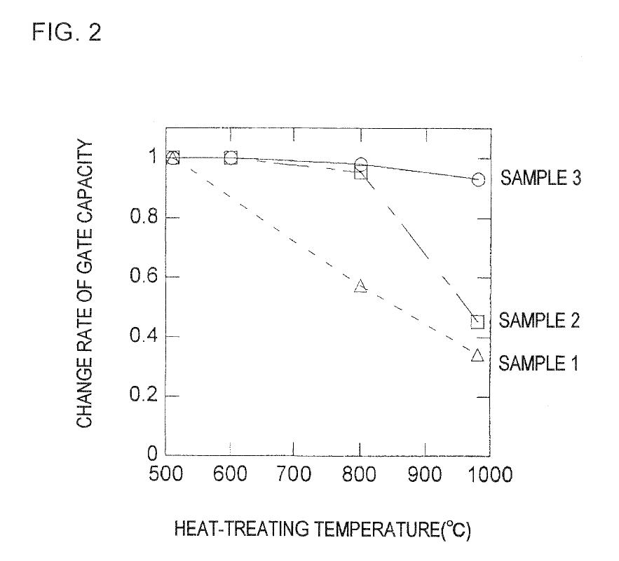

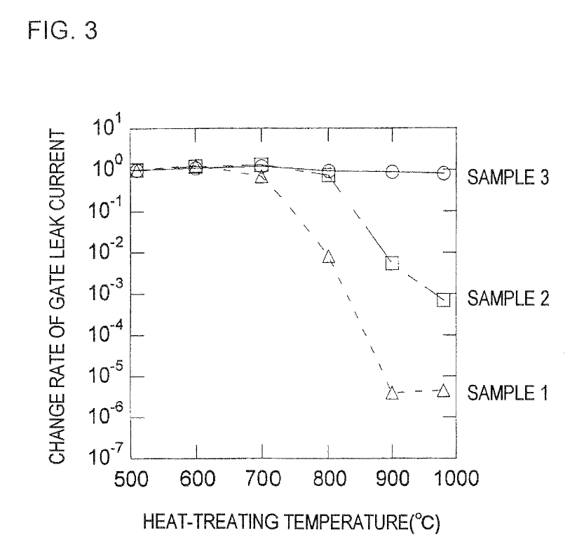

FIG. 2 and FIG. 3 show the heat-treating temperature dependency of the gate capacitance and that of the gete leak current.

Sample 1 shows a case in which a titanium nitride film with no orientation was used, the film was deposited by the CVD method using TiCl₄ and NH₃ as a raw material. And the density of the titanium nitride film was 4.5 g/cm³. Sample 2 and sample 3 show a case in which a titanium nitride film by a reactive sputtering method was used. In both cases, the orientation of the titanium nitride film is an orientation {100}. The titanium nitride film of sample 2 was formed according to the method illustrated in the above-described embodiment, except that the substrate temperature was 250° C., the pressure was 0.5 Pa and the direct current electric power was 15 kW, and the density was 5.3 g/cm³. The titanium nitride film of sample 3 was formed according to the method illustrated in the above-described embodiment (the substrate temperature: room temperature, the pressure: 0.2 Pa, and the direct current electric power: 1 kW), and the density was 5.6 g/cm³.

When a film with random crystal orientation and a low density was used (sample 1), an interface reaction between the titanium nitride film and the hafnium silicon oxy-nitride was generated and the EOT of the gate dielectric film increased when the heat-treating temperature was high. Accordingly, the change of the gate capacitance and the change of the gate leak current were large as shown in FIG. 2 and FIG. 3. On the other hand, when a film with a high density was used (samples 2 and 3), the changes of the gate capacitance and the changes of the gete leak current caused by heat-treating were controlled. Especially, in sample 3, there were seen no substantial changes in the gate capacitance and the gete leak current even if heat-treating was performed at 1000° C.

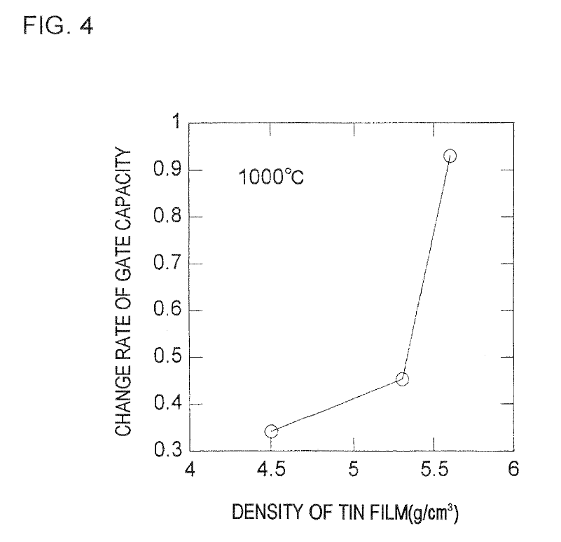

In FIG. 4, the change rates in the gate capacitance before and after the heat-treating at 1000° C. are plotted against the density of the titanium nitride film. As shown in FIG. 4, there has been obtained effects that reduction in the gate capacitance is controlled in the case of a density of 5 g/cm³ or more. Therefore, according to the present embodiment, there can be obtained a stack structure of a metal gate/high-k gate dielectric film, wherein the resistance to heat-treating (activation heat-treating in a source-drain region and the like) performed in general complementary-type MISFET integration processes is improved.

The present invention is preferably applied to a p-type MISFET, but can be also applied to an n-type MISFET. The control of the threshold voltage can be performed by the kinds of impurities, the densities of impurities, and the kinds of the gate dielectric films. When a silicon on insulator (SOI) is used, the control can be performed to an appropriate threshold, using low-density impurities in the silicon layer, in the case of an n-type transistor, and, also, in the case of a p-type transistor because the work function of the titanium nitride is in the vicinity of the center (mid-gap) in the band gap of silicon.

It is apparent that the present invention is not limited to the above embodiment, and maybe modified and changed without departing from the scope and spirit of the invention.

DESCRIPTION OF THE REFERENCE NUMERALS

What is claimed is:

1. A semiconductor device having an insulated-gate field-effect transistor, wherein said insulated-gate field-effect transistor has:
a gate insulating film including a high-k dielectric film; and
a gate electrode having a laminated structure including a first conductive layer and a second conductive layer which has a lower resistivity than that of said first conductive one, and
said first conductive layer is provided on and in contact with said high-k dielectric film, and includes titanium nitride with a density of 5 g/cm³ or more.

2. The semiconductor device according to claim 1,
wherein said first conductive layer includes titanium nitride with a density of 5.5 g/cm³ or more.

3. The semiconductor device according to claim 1,
wherein said first conductive layer includes titanium nitride in {100} orientation.

4. The semiconductor device according to claim 1,
wherein said second conductive layer includes metal.

5. The semiconductor device according to claim 1,
wherein said second conductive layer includes tungsten, or molybdenum.

6. The semiconductor device according to claim 1,
wherein said second conductive layer has a laminated structure including a silicide layer and an n-type or p-type polysilicon layer.

7. The semiconductor device according to claim 6,
wherein said silicide layer is a silicide layer including at least Ni and Si.

8. The semiconductor device according to claim 1,
wherein said high-k dielectric film includes at least one of a material selected from silicon oxy-nitride, hafnium silicon oxy-nitoride, hafnium silicate, hafnia, zirconium silicon oxy-nitoride, zirconium silicate, zirconia, hafnium aluminate, lanthanum oxide, alumina, ceria, yttria, and gadolinium oxide.

9. The semiconductor device according to claim 1,
wherein said high-k dielectric film includes oxide containing hafnium.
